(19) United States
(12) Patent Application Publication
(10) Pub. No.: US 2005/0030723 A1
(43) Pub. Date: Feb. 10, 2005

(54) Fully-molded or lidded circuit module assembly having edge-stiffening interlock features

(76) Inventors: Jeffrey Alan Miks, Chandler, AZ (US); John Armando Miranda, Chandler, AZ (US); Curtis Michael Zwenger, Chandler, AZ (US)

Correspondence Address: WEISS & MOY PC, 4204 NORTH BROWN AVENUE, SCOTTSDALE, AZ, 85251, US

(21) Appl. No.: 10/370,199

(22) Filed: Feb. 19, 2003

(51) Int. Cl. H05K 5/02

(52) U.S. Cl. 361/752; 174/52.2

(57) ABSTRACT

A fully-molded or lidded circuit module assembly having edge-stiffening interlock features provides packaging for memory modules and other circuit modules, while preventing de-lamination of the housing from the circuit supporting structure. The interlock features are provided around the periphery of the circuit supporting structure, which is generally a laminated circuit substrate, and mating features are provided on a lid that interlock with the interlock features or are generated by molding an encapsulation around the circuit supported structure in a fully-molded assembly. The interlocked assembly has added strength in bending, twisting or dropping, preventing internal de-lamination or lid detachment from causing circuit module failure.

### CROSS-REFERENCE TO RELATED APPLICATIONS

The present application is related to co-pending U.S. patent application Ser. No. 09/955,190, entitled “LEAD-FRAME METHOD AND ASSEMBLY FOR INTERCONNECTING CIRCUITS WITHIN A CIRCUIT MODULE”, filed Sep. 19, 2001 and Ser. No. 10/251,410 entitled “LEAD-FRAME METHOD AND CIRCUIT MODULE ASSEMBLY INCLUDING EDGE STIFFENER”, filed Sep. 20, 2002. Both of the above-referenced applications have at least one common inventor with the present application and are assigned to the same assignee.

### FIELD OF THE INVENTION

The present invention relates generally to circuit module packaging, and more specifically, to a method and assembly for manufacturing a circuit module, including edge-stiffening features.

### BACKGROUND OF THE INVENTION

Removable circuit modules or cards are increasing in use to provide storage and other electronic functions for devices such as digital cameras, personal computing devices and personal digital assistants (PDAs). New uses for memory cards include multi-media cards and secure digital cards.

Assembly of a circuit module typically involves attachment of one or more integrated circuit dies to a carrier or substrate. Carrier types include lead-frame assemblies as described in the above-referenced patent application. Substrates used in circuit modules are generally laminated circuit boards. For substrate-based multi-media cards, as well as other small form-factor applications, a cover is typically attached over the substrate to match the outline dimensions specified for the circuit module.

Typically, the covers are manually assembled to a substrate-based circuit module using a silicone adhesive that is applied over the inside lower surface of the cover or over the top of an encapsulant covering the dies, and the cover is pressed onto the circuit module.

However, when such a circuit module is flexed, bent or dropped, the adhesive attaching the cover to the substrate is stressed, and the cover will separate from the substrate.

Therefore, it would be desirable to provide circuit modules wherein no cover separation occurs in bending or flexure.

### SUMMARY OF THE INVENTION

A substrate-based circuit module assembly and method therefor provides packaging for memory modules and other circuit modules. The circuit module assembly comprises one or more integrated circuits for providing an electronic function of the circuit module, a substrate for mounting the integrated circuits, and a housing providing the outside form factor of the circuit module.

The housing may consist of an encapsulation attached to the substrate and surrounding the integrated circuits that extends to the outer dimensions of the circuit module on at least a top and the sides of the circuit module and may also extend around the substrate to provide the bottom side of the circuit module. The substrate may include interlock features for interlocking with mating features that are molded into the housing and the interlock features may constitute means for molding the mating features by molding the housing around a substrate with interlock features. The circuit module may also include an inner encapsulation covering the integrated circuits and a top side of the substrate which is subsequently covered by molding the housing over the inner encapsulation. Interlock features may be provided on the substrate, the inner encapsulation or both.

Alternatively, the housing may comprise a substrate to which a lid having mating features is attached by an adhesive, providing resistance to separation of the adhesive by strengthening the mechanical interlocking of the lid to the substrate. The alternative embodiment may also include an inner encapsulant and interlock features may be provided on the substrate, the inner encapsulation or both.

### BRIEF DESCRIPTION OF THE DRAWINGS

FIG. 1A is a pictorial diagram depicting a top view of a substrate assembly forming part of a circuit module in accordance with an embodiment of the invention;

FIG. 1B is a pictorial diagram depicting a top view of a substrate assembly forming part of a circuit module in accordance with an embodiment of the invention;

FIG. 1C is a pictorial diagram depicting a side view of a lid forming part of a circuit module in accordance with an embodiment of the invention;

FIG. 1D is a pictorial diagram depicting a bottom inside view of a lid forming part of a circuit module in accordance with an embodiment of the invention;

FIG. 2A is a pictorial diagram depicting a cross-sectional side view of a fully-molded circuit module in accordance with an embodiment of the invention; and

FIG. 2B is a pictorial diagram depicting cross-sectional views of shapes for forming mating and interlocking features in a circuit module in accordance with various embodiments of the invention.

The invention, as well as a preferred mode of use and advantages thereof, will best be understood by reference to the following detailed description of illustrative embodiments when read in conjunction with the accompanying drawings, wherein like reference numerals indicate like parts throughout.

### DETAILED DESCRIPTION

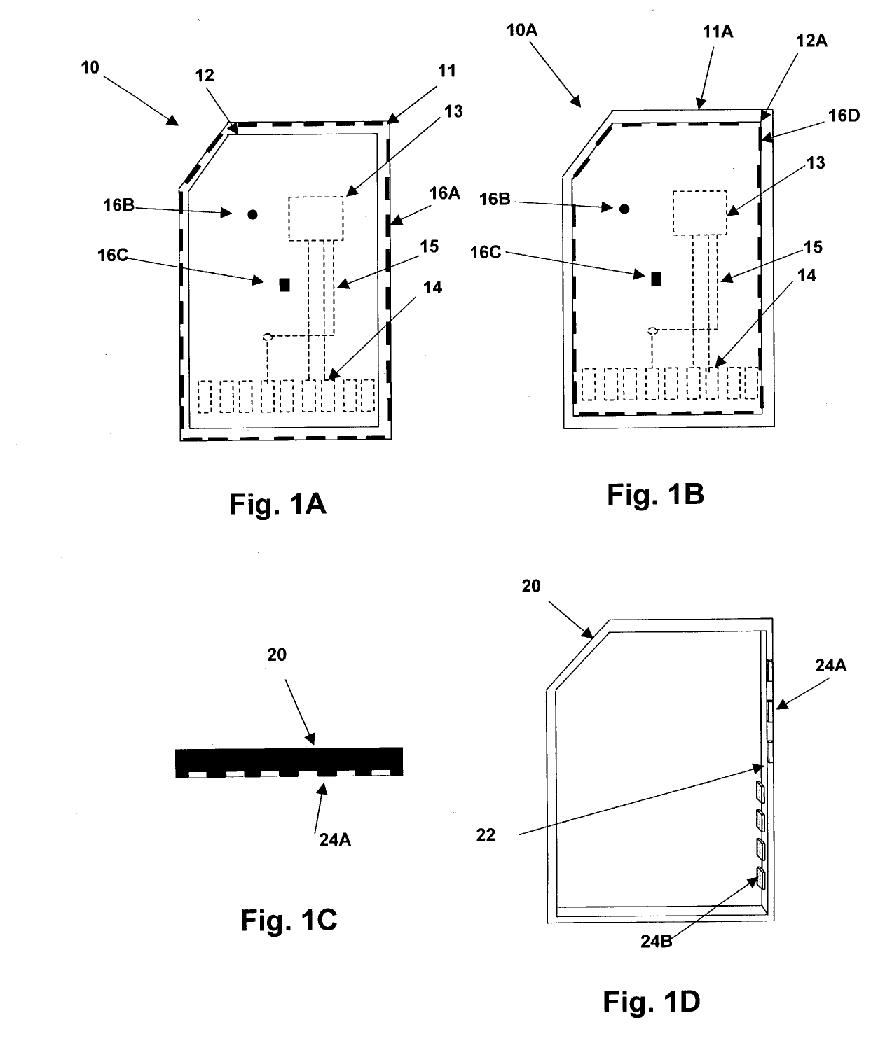

Referring now to FIG. 1A, a substrate assembly 10 for forming a circuit module in accordance with an embodiment of the invention is depicted. Substrate assembly 10 is depicted as adapted for use in a circuit module as used in various multimedia memory applications. The present invention is also applicable to cards and modules having other outlines such as secure digital cards and various compact flash memory cards, etc. The present invention applies to peripheral device cards (I/O cards), as well.

A substrate 11 to which integrated circuit dies 13 are attached and circuit terminals (contacts) 14 are included on the bottom side, is optionally covered by an inner encapsulant 12 that is bonded to substrate 11. Circuit contacts 14 are electrically connected to integrated circuit dies 13 by conductive patterns 15 within substrate 11. Substrate assembly 10 forms the electronic portion of the circuit module, which must be packaged with a housing which covers the top and edges and optionally the bottom of substrate assembly 10 to form a package that conforms with the outlines specified for the particular MMC, SD card, etc.

A suitable housing can be provided by a lid or cover that is applied over substrate assembly 10 using an adhesive. Alternatively, a housing may be molded over substrate assembly 10, forming a fully-molded circuit module. In either housing embodiment type, twisting or bending of the circuit module may separate substrate assembly 10 from the housing either completely or internally, causing distortion or separation of portions of the circuit module. The bending of the circuit module may also cause other internal failure such as cracking of substrate 11, breakage of conductive patterns 15 and cracking or separation of dies 13.

The present invention is directed to various solutions to the separation problem described above. In general, the embodiments provide stiffening of the circuit module package so that an applied bending, twisting or impact force yields reduced bending of the circuit module. The circuit module is stiffened by adding one or more of various interlock features 16A, 16B and 16C to substrate assembly 10 and either providing corresponding mating features on a lid, so that the lid interlocks with substrate assembly 10, or in a fully-molded housing embodiment, molding the housing around the interlock features so that mating features are formed in the molded housing. Additionally, the circuit module may be made fully-molded, in which case the module can be constructed with or without interlock features.

FIG. 1A shows interlock features in the form of notches 16A in substrate 11 disposed around the periphery of substrate 11 at regular intervals. Further interlock features shown in FIG. 1A are circular cutout 16B and rectangular cutout 16C provided through substrate 11. Interlock features that strengthen a circuit module in bending axes may be located on the edge of substrate (as exemplified by notches 16A), through the substrate (as exemplified by cut-outs 16B and 16C) or, as shown in FIG. 1B, by interlock features formed in optional inner encapsulant 12A. In general, interlock features may be located near the edges, stiffening the edges and therefore the circuit module as a whole, or interlock features may be located in convenient areas between circuits through the substrate, which will stiffen the entire circuit module.

FIG. 1B shows notches 16D similar to notches 16A of FIG. 1A, but notches 16D are formed around the periphery of inner encapsulant 12. Any of the above interlock features may be used in combination, including the combination of notches 16A on the edge of substrate 11 and notches or other interlock features provided on an inner encapsulation such as notches 16D.

Referring now to FIG. 1C, a lid 20 is shown illustrating mating features 24A suitable for interlocking with notches 16A. Mating features for interlocking with interlock features on the substrate edge such as those illustrated will generally be tabs extending downward from the plane of the top surface of substrate 11 to the bottom surface of substrate 11. A fully-molded housing can also be illustrated by the outline shown in FIG. 1C, as the shape of the housing can externally be made identical to lid 20 and mating features (tabs) 24A can be generated by molding around a notched substrate, such as substrate 11, when molding a housing over substrate assembly 10.

Referring now to FIG. 1D, a bottom perspective view of lid 20 prior to attachment to a circuit module is shown. Inner surface 22 of lid has mating features 24B disposed to mate with interlock features of an inner encapsulation such as notches 16D of inner encapsulation 12A. Tab 24A illustrates a mating feature for interlocking with interlock features disposed around the periphery of the substrate such as notches 16A disposed around substrate 11. Similarly, a fully-molded housing encapsulated over an inner encapsulant having interlock features will generate mating features such as those illustrated by bumps 24B.

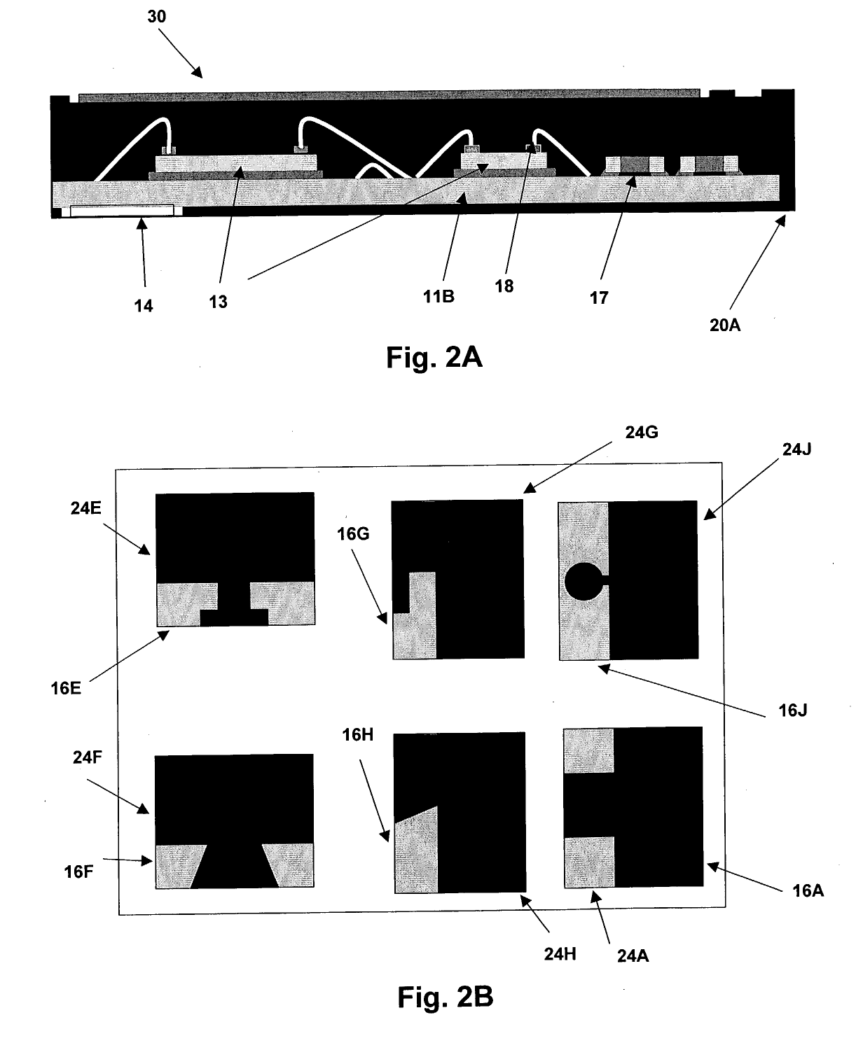

Referring now to FIG. 2A, a cross-sectional side view of a fully-molded circuit module 30 in accordance with an embodiment of the invention is depicted. Circuit contacts 14 are provided by a raised conductive layer on substrate 11B, which is generally a laminated circuit board substrate. Dies 13 and passive components 17 are mounted on substrate and dies are wire-bonded via wires 18 to the substrate 11B conductive patterns, that electrically interface the electronics to contacts 14. Housing 20A is molded around substrate 11B on all sides, although alternatives to circuit module 30 may be made without molding encapsulant on the bottom side of substrate 11B and/or without molding encapsulant around any or all of the sides of substrate 11B, in which case the conductive material forming contacts 14 can be made thinner. Housing 20A completely covers dies 13, wires 18 and passive components 17 as shown, but an inner encapsulation may also be used prior to final molding of the housing and may provide inventory advantage in the protected encapsulated assemblies can be stored without the final encapsulation which may have a shape, color or embossing that is dictated by a particular application. Housing 20A and substrate 11B preferably include interlock features for stiffening the edges the circuit module 30, providing enhanced protection against damage due to bending, flexure or impact.

Referring now to FIG. 2B, a variety of shapes that may be used to generate interlocking features and mating features in accordance with various embodiments of the invention are shown in a table. Interlock feature 16E is an example of a shape suitable for use with cut-outs through a substrate such as interlock features 16B and 16C of FIGS. 1A and 1B. Interlocking features 16E can be located anywhere along the perimeter or inboard of the substrate edge.

A housing may be molded over the substrate and mating feature 24E will be generated through the cut-out having a counter-bore retaining shape as shown. Interlock feature 16F is similarly suitable for such applications, showing a counter-sink shape generated as a mating feature 24F through counter sunk cut-out 16F.

Interlock features 16G, 16H are examples of interlock features suitable for alternative shapes that may be applied to interlock features such as tabs 16A of FIG. 1A or tabs 16B of FIG. 1B. Interlock feature 16G generates a stair-step edge mating feature having an overlapping extension when over-molded, or provides a shape that is compatible with a separately fabricated lid having mating feature 24G disposed thereon, by press fitting the substrate assembly to the from above, which will not cause any interference between the stairstep extension of the mating feature 24G and the interlock feature 16G. Interlock feature 16G has a chamfered edge to generate or mate with an inverse chamfered edge of a mating feature 24H on a molded housing or lid.

Hemispherical interlock feature 16J may be used at the edge of a substrate or as a cut-out mating feature (a vent hole may be provided through from interlock feature 16J side to permit exit of air during a molding process. Corresponding mating feature 24J can be fit from above in case of a lid or molded around interlock feature 16J for a fully-molded application.

Mating feature 16A is depicted for comparison to the other examples, showing the profile of a tab interlock feature and a notch mating feature 24A. The other examples have advantages in that they provide interlock in two or three axes (depending on the vertical profile), while the notch only provides interlock in the direction that the sides of the tab contact the notch. Other shapes that may be used will be apparent to those skilled in the art and the examples shown in FIG. 2B are intended to provide examples and are not limiting as to the shapes that may be employed to provide interlocking and mating features on the substrate assembly or housing of a circuit module.

The above description of embodiments of the invention is intended to be illustrative and not limiting. Other embodiments of this invention will be obvious to those skilled in the art in view of the above disclosure and fall within the scope of the present invention.

1-10. canceled.

11. A circuit module, comprising:
a substrate assembly including at least one semiconductor die for providing an electronic function of the circuit module and a substrate for mounting the at least one semiconductor die within the circuit module, the substrate providing a plurality of terminals on a bottom side thereof for connection of the at least one semiconductor die to an external device, and wherein the substrate includes conductive patterns for connecting electrical connections of the at least one semiconductor die to the terminals; and
a fully-molded housing formed by molding around the substrate assembly and covering the substrate assembly on at least a top of the substrate assembly for providing exterior surfaces of the circuit module, wherein the terminals are exposed on an exterior surface of the circuit module.

12. The circuit module of claim 11, wherein the housing further surrounds the substrate assembly on at least the top and one side of said substrate assembly.

13. The circuit module of claim 11, wherein the housing is molded over the bottom of the substrate assembly, exclusive of the terminals.

14. The circuit module of claim 11, wherein the substrate assembly further includes a plurality of interlock features disposed on the substrate assembly, and wherein the housing further includes a plurality of mating features formed by molding the housing around the interlock features, whereby the circuit module is stiffened.

15. The circuit module of claim 14, wherein the interlock features are disposed around the periphery of the substrate.

16. The circuit module of claim 14, wherein the substrate assembly further comprises an inner encapsulant disposed over at least a top side of the substrate, and wherein the interlock features are formed in the inner encapsulant, whereby the lid is retained to the inner encapsulant by molding of mating features of the housing around the interlock features of the inner encapsulant.

17. The circuit module of claim 14, wherein the interlock features comprise one of a counter-bore or counter-sunk well formed through the substrate assembly in a direction perpendicular to a primary plane of the substrate assembly, whereby the mating features include extensions formed by molding the housing through the wells.

18. The circuit module of claim 14, wherein the interlock features are rectangular notches provided at a regular interval on the periphery of the substrate assembly and wherein the mating features are provided by rectangular protrusions of the housing formed by molding within the rectangular notches of the substrate assembly.

19. The circuit module of claim 14, wherein the interlock features are notches having a chamfered profile in a plane parallel to a primary plane of the substrate and provided at intervals in the substrate assembly and wherein the mating features are provided by molding the housing around the notches of the substrate assembly.

20. The circuit module of claim 14, wherein the interlock features are notches having a hemispherical profile in a plane parallel to a primary plane of the substrate and provided at a regular interval on the periphery of the substrate assembly and wherein the mating features,are provided by molding the housing into the notches of the substrate assembly.

21. The circuit module of claim 14, wherein the interlock features include a first extension extending perpendicular to the periphery of the substrate assembly in a plane bounding the periphery of the substrate assembly, and a second extension extending parallel to the periphery of the substrate assembly, whereby a stair-step edge is formed for interlocking in two axes by molding the housing around the stair-step edge.

22. A circuit module, comprising:
a substrate assembly including at least one semiconductor die for providing an electronic function of the circuit module and a substrate for mounting the at least one semiconductor die within the circuit module, the substrate assembly providing a plurality of terminals for connection of the at least one semiconductor die to an external device;
a fully-molded housing formed by molding around the substrate assembly and covering the substrate assembly on at least a top of the substrate assembly for providing exterior surfaces of the circuit module assembly, wherein the terminals are disposed on an exterior surface of the housing; and
means for interlocking at least one edge of the substrate assembly with the housing, whereby the housing is more securely retained to the substrate assembly.

23. A method for manufacturing a circuit module, comprising:
attaching at least one semiconductor die to a substrate having a plurality of terminals disposed on the bottom side thereof for connection of the semiconductor die to an external device;
electrically connecting the semiconductor die to conductive patterns of the substrate;
and
molding a housing over at least a top side of the substrate to form external surfaces of the circuit module.

24. Canceled.

25. The method of claim 22, further comprising forming interlock features in the substrate assembly, whereby the molding forms mating features by molding around the interlock features.

26. The method of claim 25, wherein the forming interlock features forms interlock features on the edges of the substrate.

27. The method of claim 25, further comprising applying an inner encapsulant over the semiconductor die to form the substrate assembly, and wherein the forming interlock features forms interlock features in an inner encapsulant of the substrate assembly.

28. A circuit module, comprising:
a substrate assembly including at least one semiconductor die for providing an electronic function of the circuit module and a substrate for mounting the at least one semiconductor die within the circuit module, the substrate providing a plurality of terminals conformal with a bottom side of the circuit module for providing connection to electrical terminals of the semiconductor die via removable contact with terminals of a mating receptacle of an external device, and wherein the substrate includes conductive patterns for connecting the electrical connections of the at least one semiconductor die to the terminals; and
a fully-molded housing formed by molding around the substrate assembly and covering the substrate assembly on at least a top of the substrate assembly for providing exterior surfaces of the circuit module.

29. The circuit module of claim 28, wherein the housing further surrounds the substrate assembly on at least the top and one side of said substrate assembly.

30. The circuit module of claim 28, wherein the housing is molded over the bottom of the substrate assembly, exclusive of an area of exposure of the terminals.

31. The circuit module of claim 28, wherein the substrate assembly further includes a plurality of interlock features disposed on the substrate assembly, and wherein the housing further includes a plurality of mating features formed by molding the housing around the interlock features, whereby the circuit module is stiffened.

32. The circuit module of claim 31, wherein the interlock features are disposed around the periphery of the substrate.

33. The Circuit module of claim 31, wherein the substrate assembly further comprises an inner encapsulant disposed over at least a top side of the substrate, and wherein the interlock features are formed in the inner encapsulant, whereby the lid is retained to the inner encapsulant by molding of mating features of the housing around the interlock features of the inner encapsulant.

34. The circuit module of claim 31, wherein each of the interlock features contacts a corresponding mating feature along an axis perpendicular to the primary plane of the substrate, and wherein the interlock features have a height in the perpendicular axis greater than or substantially equal to the height of the substrate so that a bending force along the edge of the substrate is transferred to the area of contact of the interlock features with the mating features, whereby the circuit module is stiffened.

35. The circuit module of claim 14, wherein each of the interlock features contacts a corresponding mating feature along an axis perpendicular to the primary plane of the substrate, and wherein the interlock features have a height in the perpendicular axis greater than or substantially equal to the height of the substrate so that a bending force along the edge of the substrate is transferred to the area of contact of the interlock features with the mating features, whereby the circuit module is stiffened.
